(19) United States
(12) Patent Application Publication
(10) Pub. No.: US 2016/0322379 A1
(43) Pub. Date: Nov. 3, 2016

(54) SEMICONDUCTOR MEMORY DEVICE AND METHOD OF MANUFACTURING THE SAME

(71) Applicant: Kabushiki Kaisha Toshiba, Minato-ku (JP)

(72) Inventors: Takao OOMORI, Yokkaichi (JP); Takanobu ITOH, Yokkaichi (JP); Hisataka MEGURO, Yokkaichi (JP); Hideaki HARAKAWA, Yokkaichi (JP)

(73) Assignee: Kabushiki Kaisha Toshiba, Minato-ku (JP)

(21) Appl. No.: 14/849,167

(22) Filed: Sep. 9, 2015

Related U.S. Application Data
(60) Provisional application No. 62/153,858, filed on Apr. 28, 2015.

(51) Int. Cl. H01L 27/115; C22C 19/03; H01L 29/66; H01L 29/417; H01L 29/45

(52) U.S. Cl. CPC H01L 27/11582; H01L 29/41741; H01L 29/456; H01L 29/665; C22C 19/03

(57) ABSTRACT

According to an embodiment, a semiconductor memory device comprises a plurality of control gate electrodes, a semiconductor layer, a charge accumulation layer, and a contact. The plurality of control gate electrodes are stacked on a substrate. The semiconductor layer has one end thereof connected to the substrate, has as its longitudinal direction a direction perpendicular to the substrate, and faces the plurality of control gate electrodes. The charge accumulation layer is positioned between the control gate electrode and the semiconductor layer. The contact has its lower end connected to the substrate, and has its lower end and its upper end configured from a metal silicide.

### CROSS REFERENCE TO RELATED APPLICATIONS

This application is based on and claims the benefit of priority from prior Japanese Patent Application No. 62/153,858, filed on Apr. 28, 2015, the entire contents of which are incorporated herein by reference.

### BACKGROUND

1. Field

Embodiments described herein relate to a semiconductor memory device and a method of manufacturing the same.

2. Description of the Related Art

A flash memory that stores data by accumulating a charge in a charge accumulation layer, is known. Such a flash memory is connected by a variety of systems such as NAND type or NOR type, and configures a semiconductor memory device. In recent years, increasing of capacity and raising of integration level of such a nonvolatile semiconductor memory device have been proceeding. Moreover, a semiconductor memory device in which memory cells are disposed three-dimensionally (three-dimensional type semiconductor memory device) has been proposed to raise the integration level of the memory.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the same nonvolatile semiconductor memory device.

FIG. 3 is a perspective view showing a configuration of part of the same nonvolatile semiconductor memory device.

FIG. 4 is a perspective view showing a configuration of part of the same nonvolatile semiconductor memory device.

FIG. 5 is a plan view showing a configuration of part of the same nonvolatile semiconductor memory device.

FIG. 6 is a cross-sectional view showing a configuration of part of the same nonvolatile semiconductor memory device.

FIG. 7 is a cross-sectional view showing a configuration of part of the same nonvolatile semiconductor memory device.

FIG. 8 is a cross-sectional view showing a manufacturing step of the same nonvolatile semiconductor memory device.

FIG. 9 is a cross-sectional view showing a manufacturing step of the same nonvolatile semiconductor memory device.

FIG. 10 is a cross-sectional view showing a manufacturing step of the same nonvolatile semiconductor memory device.

FIG. 11 is a cross-sectional view showing a manufacturing step of the same nonvolatile semiconductor memory device.

FIG. 12 is a cross-sectional view showing a manufacturing step of the same nonvolatile semiconductor memory device.

FIG. 13 is a cross-sectional view showing a manufacturing step of the same nonvolatile semiconductor memory device.

FIG. 14 is a cross-sectional view showing a manufacturing step of the same nonvolatile semiconductor memory device.

FIG. 15 is a cross-sectional view showing a manufacturing step of the same nonvolatile semiconductor memory device.

FIG. 16 is a cross-sectional view showing a manufacturing step of the same nonvolatile semiconductor memory device.

FIG. 17 is a cross-sectional view showing a manufacturing step of the same nonvolatile semiconductor memory device.

FIG. 18 is a cross-sectional view showing a manufacturing step of the same nonvolatile semiconductor memory device.

FIG. 19 is a cross-sectional view showing a manufacturing step of the same nonvolatile semiconductor memory device.

FIG. 20 is a cross-sectional view showing a manufacturing step of the same nonvolatile semiconductor memory device.

FIG. 21 is a cross-sectional view showing a manufacturing step of the same nonvolatile semiconductor memory device.

### DETAILED DESCRIPTION

A semiconductor memory device according to an embodiment comprises a plurality of control gate electrodes, a semiconductor layer, a charge accumulation layer, and a contact. The plurality of control gate electrodes are stacked above a substrate. The semiconductor layer has one end thereof connected to the substrate, has as its longitudinal direction a direction perpendicular to the substrate, and faces the plurality of control gate electrodes. The charge accumulation layer is positioned between the control gate electrode and the semiconductor layer. The contact has its lower end connected to the substrate, and has its lower end and its upper end configured from a metal silicide.

Next, nonvolatile semiconductor memory devices according to embodiments will be described in detail with reference to the drawings. Note that these embodiments are merely examples, and are not shown with the intention of limiting the present invention. Moreover, each of the drawings of the nonvolatile semiconductor memory devices employed in the embodiments below is schematic, and thicknesses, widths, ratios, and so on, of layers are different from those of the actual nonvolatile semiconductor memory devices.

The embodiments below relate to nonvolatile semiconductor memory devices having a structure in which a plurality of MONOS (Metal-Oxide-Nitride-Oxide-Semiconductor) type memory cells (transistors) are provided in a height direction, each of the MONOS type memory cells including: a semiconductor layer acting as a channel provided in a column shape perpendicularly to a substrate; and a gate electrode layer provided on a side surface of the semiconductor layer via a charge accumulation layer. However, this is also not intended to limit the present invention, and the present invention may be applied also to a memory cell of another form of charge accumulation layer, for example, a SONOS (Semiconductor-Oxide-Nitride-Oxide-Semiconductor) type memory cell, or a floating gate type memory cell, and so on.

### First Embodiment

### Semiconductor Memory Device

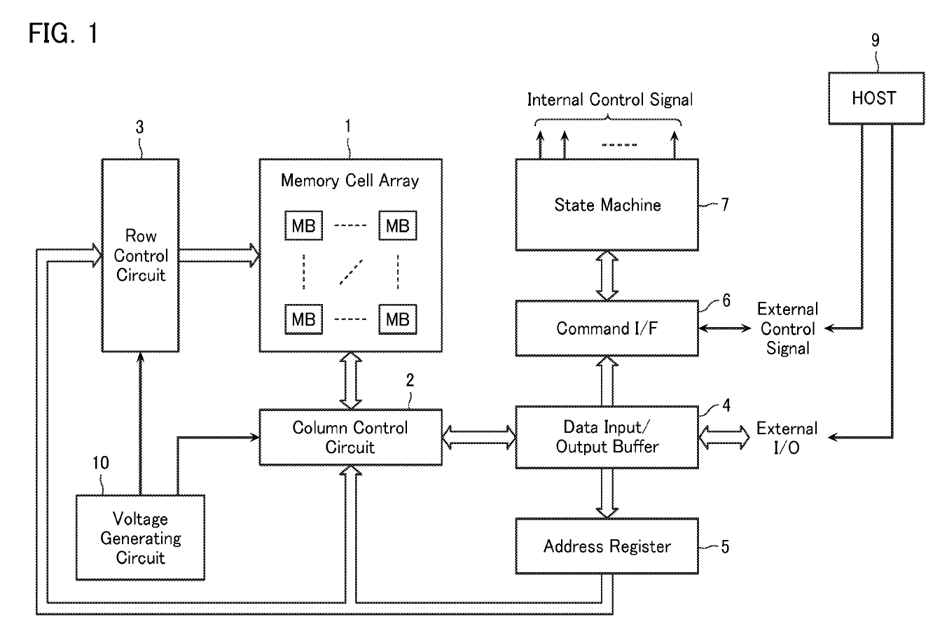

FIG. 1 is a block diagram of a nonvolatile semiconductor memory device according to a first embodiment. The nonvolatile semiconductor memory device stores write data inputted from an external host 9, in a certain address in a memory cell array 1. In addition, the nonvolatile semiconductor memory device reads data from a certain address in the memory cell array 1, and outputs the data to the external host 9.

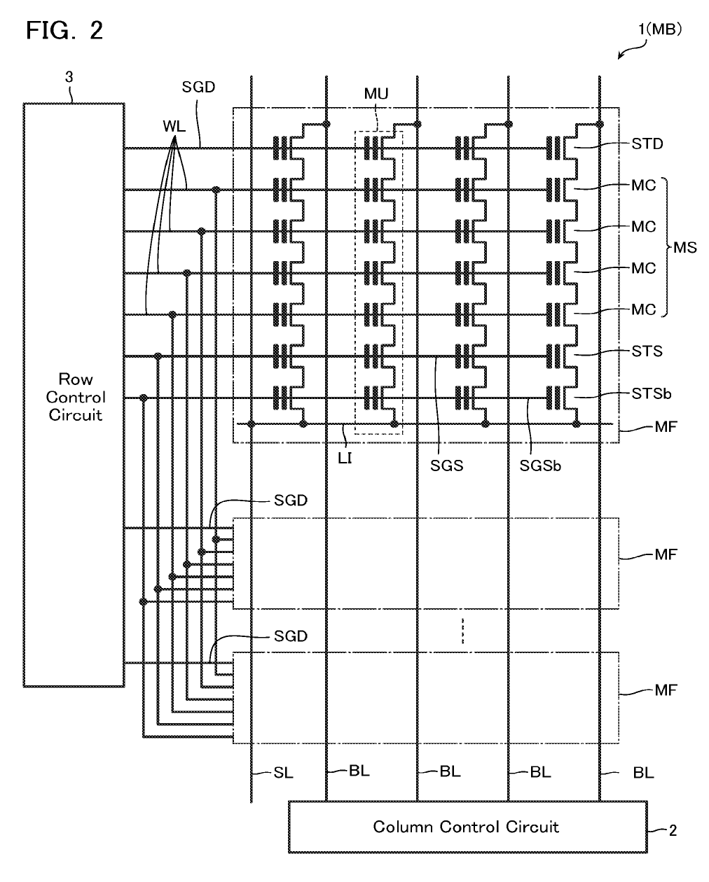

That is, as shown in FIG. 1, the same nonvolatile semiconductor memory device comprises the memory cell array 1 that stores data. The memory cell array 1 comprises a plurality of memory blocks MB. As will be described later with reference to FIG. 2, these memory blocks MB each comprise: a plurality of memory cells MC; and a bit line BL and a word line WL connected to these memory cells MC.

As shown in FIG. 1, the nonvolatile semiconductor memory device comprises a column control circuit 2 provided in a periphery of the memory cell array 1. The column control circuit 2 transfers a voltage generated by a voltage generating circuit 10 to a desired bit line BL according to inputted data. Moreover, the column control circuit 2 comprises an unillustrated sense amplifier, and detects a voltage or current of a certain bit line BL.

As shown in FIG. 1, the nonvolatile semiconductor memory device comprises a row control circuit 3 provided in a periphery of the memory cell array 1. The row control circuit 3 transfers a voltage generated by the voltage generating circuit 10 to a desired word line WL, and so on, according to inputted address data.

As shown in FIG. 1, the nonvolatile semiconductor memory device comprises an address register 5 that supplies address data to the column control circuit 2 and the row control circuit 3. The address register 5 stores address data inputted from a data input/output buffer 4.

As shown in FIG. 1, the nonvolatile semiconductor memory device comprises the voltage generating circuit 10 that supplies a voltage to the memory cell array 1 via the column control circuit 2 and the row control circuit 3. The voltage generating circuit 10 generates and outputs a voltage of a certain magnitude at a certain timing, based on an internal control signal inputted from a state machine 7.

As shown in FIG. 1, the nonvolatile semiconductor memory device comprises the state machine 7 that inputs the internal control signal to the voltage generating circuit 10, and so on. The state machine 7 receives command data from the host 9, via a command interface 6, and performs management of read, write, erase, input/output of data, and so on.

As shown in FIG. 1, the nonvolatile semiconductor memory device comprises the data input/output buffer 4 which is connected to the external host 9 via an I/O line. The data input/output buffer 4 receives write data from the external host 9, and transfers the write data to the column control circuit 2. Moreover, the data input/output buffer 4 receives command data from the external host 9, and transfers the command data to the command interface 6. In addition, the data input/output buffer 4 receives address data from the external host 9, and transfers the address data to the address register 5. Furthermore, the data input/output buffer 4 receives read data from the column control circuit 2, and transfers the read data to the external host 9.

As shown in FIG. 1, the nonvolatile semiconductor memory device comprises the command interface 6 that receives an external control signal from the external host 9. The command interface 6 determines which of write data, command data, and address data inputted to the data input/output buffer 4 is, based on the external control signal inputted from the external host 9, and controls the data input/output buffer 4. In addition, the command interface 6 transfers to the state machine 7 command data received from the data input/output buffer 4.

Note that the column control circuit 2, the row control circuit 3, the state machine 7, the voltage generating circuit 10, and so on, configure a control circuit that controls the memory cell array 1.

Next, a circuit configuration of part of the memory cell array 1 according to the present embodiment will be described with reference to FIG. 2. FIG. 2 is an equivalent circuit diagram showing a configuration of the memory block MB configuring the memory cell array 1. In the memory block MB shown in FIG. 2, a certain drain side select gate line SGD and a certain word line WL are selected by the row control circuit 3, whereby a certain number of memory cells MC are selected. Moreover, data of these memory cells MC is read, or data is written to these memory cells MC by the column control circuit 2.

As shown in FIG. 2, the memory blocks MB each comprise a plurality of memory fingers MF. Commonly connected to these plurality of memory fingers MF are a plurality of the bit lines BL and a source line SL. Each of the memory fingers MF is connected to the column control circuit 2 via the bit lines BL, and is connected to an unillustrated source line driver via the source line SL.

The memory finger MF comprises a plurality of memory units MU that have their one ends connected to the bit lines BL and have their other ends connected to the source line SL via a source contact LI. The memory units MU included in one memory finger MF are all connected to different bit lines BL.

As shown in FIG. 2, the memory unit MU comprises a plurality of the memory cells MC connected in series. As will be mentioned later, the memory cell MC comprises a semiconductor layer, a charge accumulation layer, and a control gate, and accumulates a charge in the charge accumulation layer based on a voltage applied to the control gate, thereby changing a threshold value of the memory cell MC. Note that hereafter, the plurality of memory cells MC connected in series will be called a “memory string MS”. The row control circuit 3 transfers a voltage to a certain word line WL, thereby transferring this voltage to the control gate of a certain memory cell MC in the memory string MS.

As shown in FIG. 2, commonly connected to the control gates of pluralities of the memory cells MC configuring different memory strings MS are, respectively, the word lines WL. These pluralities of memory cells MC are connected to the row control circuit 3 via the word lines WL. Moreover, in the example shown in FIG. 2, the word lines WL are provided independently to each of the memory cells MC included in the memory unit MU, and are provided commonly for all of the memory units MU included in one memory block MB.

As shown in FIG. 2, the memory unit MU comprises a drain side select gate transistor STD connected between the memory string MS and the bit line BL. Connected to a control gate of the drain side select gate transistor STD is the drain side select gate line SGD. The drain side select gate line SGD is connected to the row control circuit 3, and selectively connects the memory string MS and the bit line BL based on an inputted signal. Moreover, in the example shown in FIG. 2, the drain side select gate line SGD is provided independently to each of the memory fingers MF, and is commonly connected to the control gates of all of the drain side select gate transistors STD in the memory finger MF. The row control circuit 3 selects a certain drain side select gate line SGD, thereby selectively connecting all of the memory strings MS in a certain memory finger MF to the bit lines BL.

Moreover, as shown in FIG. 2, the memory unit MU comprises a source side select gate transistor STS and a lowermost layer source side select gate transistor STSb that are connected between the memory string MS and the source contact LI. Connected to a control gate of the source side select gate transistor STS is a source side select gate line SGS. In addition, connected to a control gate of the lowermost layer source side select gate transistor STSb is a lowermost layer source side select gate line SGSb. Moreover, in the example shown in FIG. 2, the source side select gate line SGS is commonly connected to all of the source side select gate transistors STS in the memory block MB. Similarly, the lowermost layer source side select gate line SGSb is commonly connected to all of the lowermost layer source side select gate transistors STSb in the memory block MB. The row control circuit 3 connects all of the memory strings MS in the memory block MB to the source line SL, based on an inputted signal.

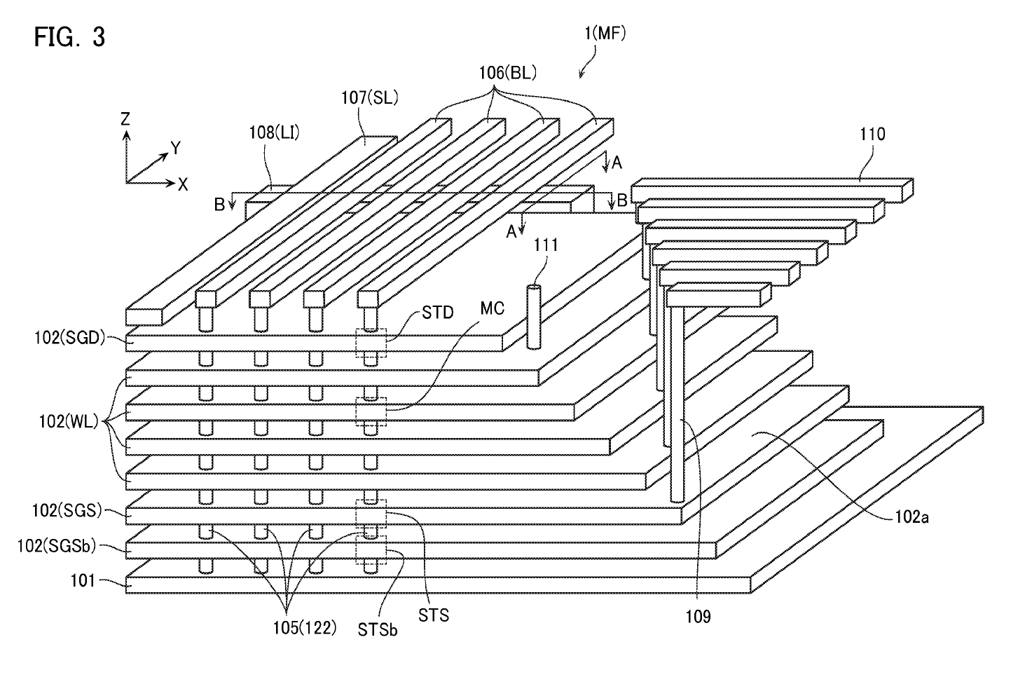

Next, a schematic configuration of the memory cell array 1 will be described with reference to FIG. 3. FIG. 3 is a schematic perspective view showing a configuration of part of the memory finger MF. Note that in FIG. 3, part of the configuration is omitted. Moreover, the configuration shown in FIG. 3 is merely an example, and a specific configuration may be appropriately changed. For example, in FIG. 3, seven layers of conductive layers 102 are stacked, but about 60 layers of the conductive layers 102 may be stacked.

As shown in FIG. 3, the memory finger MF comprises: a substrate 101; and a plurality of the conductive layers 102 stacked in a Z direction on the substrate 101. In addition, the memory finger MF includes a plurality of memory columnar bodies 105 extending in the Z direction. As shown in FIG. 3, an intersection of the conductive layer 102 and the memory columnar body 105 functions as the lowermost layer source side select gate transistor STSb, the source side select gate transistor STS, the memory cell MC, or the drain side select gate transistor STD. The conductive layer 102 is configured from a conductive layer of the likes of tungsten (W) or polysilicon, for example, and functions as each of the word line WL and control gate electrode of the memory cell MC, the source side select gate line SGS and control gate electrode of the source side select gate transistor STS, the drain side select gate line SGD and control gate electrode of the drain side select gate transistor STD, or the lowermost layer source side select gate line SGSb and control gate electrode of the lowermost layer source side select gate transistor STSb.

As shown in FIG. 3, the plurality of conductive layers 102 are formed in steps, at their ends in an X direction. That is, the conductive layer 102 comprises a contact portion 102a that does not face a lower surface of the conductive layer 102 positioned in a layer above it. Moreover, the conductive layer 102 is connected to a via contact wiring line 109 at this contact portion 102a. Moreover, a wiring line 110 is provided at an upper end of the via contact wiring line 109. Note that the via contact wiring line 109 and the wiring line 110 are configured from a conductive layer of the likes of tungsten.

In addition, as shown in FIG. 3, the memory finger MF comprises a support 111. The support 111 communicates with holes provided in the plurality of conductive layers 102. The support 111 supports a shape of an unillustrated insulating layer provided between the conductive layers 102, in a manufacturing step.

In addition, as shown in FIG. 3, the memory finger MF comprises a conductive layer 108. The conductive layer 108 faces side surfaces in a Y direction of the plurality of conductive layers 102, and has a plate-like shape extending in the X direction and the Y direction. That is, the conductive layer 108 has a width in the X direction which is sufficiently larger than a width in the Y direction (has the X direction as its longitudinal direction), in the XY plane, and has a width in the Z direction which is sufficiently larger than the width in the Y direction (has the Z direction as its longitudinal direction), in the YZ plane. Moreover, in the present embodiment, the width in the X direction of the conductive layer 108 is larger than the width in the Z direction of the conductive layer 108. A lower end of the conductive layer 108 contacts the substrate 101. The conductive layer 108 is configured from a conductive layer of the likes of tungsten (W), for example, and functions as the source contact LI.

In addition, as shown in FIG. 3, the memory finger MF comprises a plurality of conductive layers 106 and a conductive layer 107 that are positioned above the plurality of conductive layers 102 and memory columnar bodies 105, are arranged in plurality in the X direction, and extend in the Y direction. The memory columnar bodies 105 are respectively connected to lower surfaces of the conductive layers 106. The conductive layer 106 is configured from a conductive layer of the likes of tungsten (W), for example, and functions as the bit line BL. Moreover, the conductive layer 108 is connected to a lower surface of the conductive layer 107. The conductive layer 107 is configured from a conductive layer of the likes of tungsten (W), for example, and functions as the source line SL.

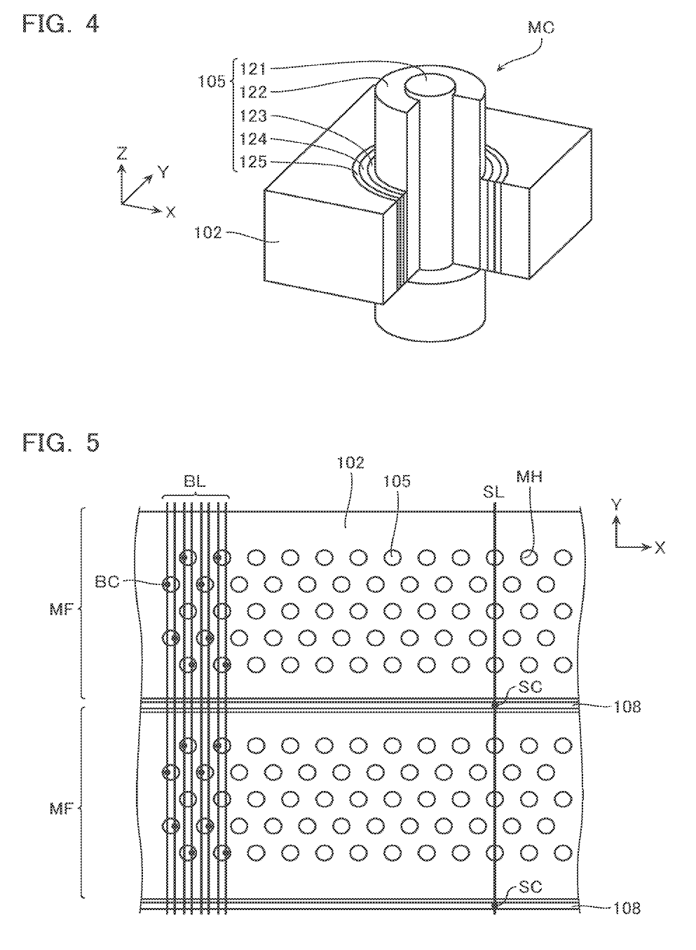

Next, a schematic configuration of the memory cell MC will be described with reference to FIG. 4. FIG. 4 is a schematic perspective view showing the configuration of the memory cell MC. Note that FIG. 4 shows the configuration of the memory cell MC, but the lowermost layer source side select gate transistor STSb, the source side select gate transistor STS, and the drain side select gate transistor STD may also be configured similarly to the memory cell MC. Note that in FIG. 4, part of the configuration is omitted.

As shown in FIG. 4, the memory cell MC is provided at an intersection of the conductive layer 102 and the memory columnar body 105. The memory columnar body 105 comprises: a core insulating layer 121; and a semiconductor layer 122, a tunnel insulating layer 123, a charge accumulation layer 124, and a block insulating layer 125 that cover a sidewall of the core insulating layer 121.

The core insulating layer 121 is configured from an insulating layer of the likes of silicon oxide (SiO₂), for example. The semiconductor layer 122 is configured from a semiconductor layer of the likes of polysilicon, for example, and functions as a channel of the memory cell MC, the lowermost layer source side select gate transistor STSb, the source side select gate transistor STS, and the drain side select gate transistor STD. The tunnel insulating layer 123 is configured from an insulating layer of the likes of silicon oxide (S102), for example. The charge accumulation layer 124 is configured from an insulating layer capable of accumulating a charge, of the likes of silicon nitride (SiN), for example. The block insulating layer 125 is configured from an insulating layer of the likes of silicon oxide (SiO₂), for example.

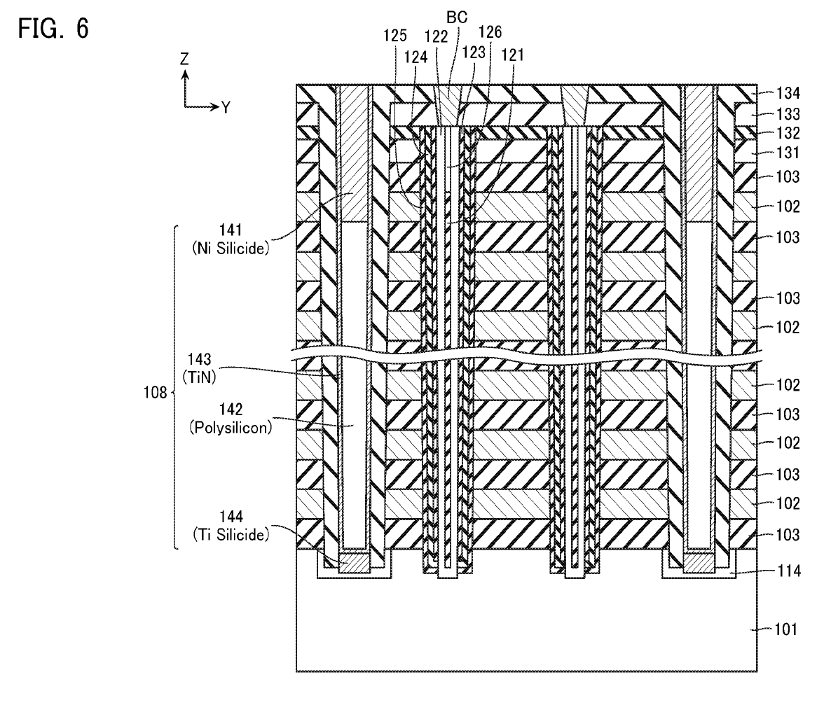

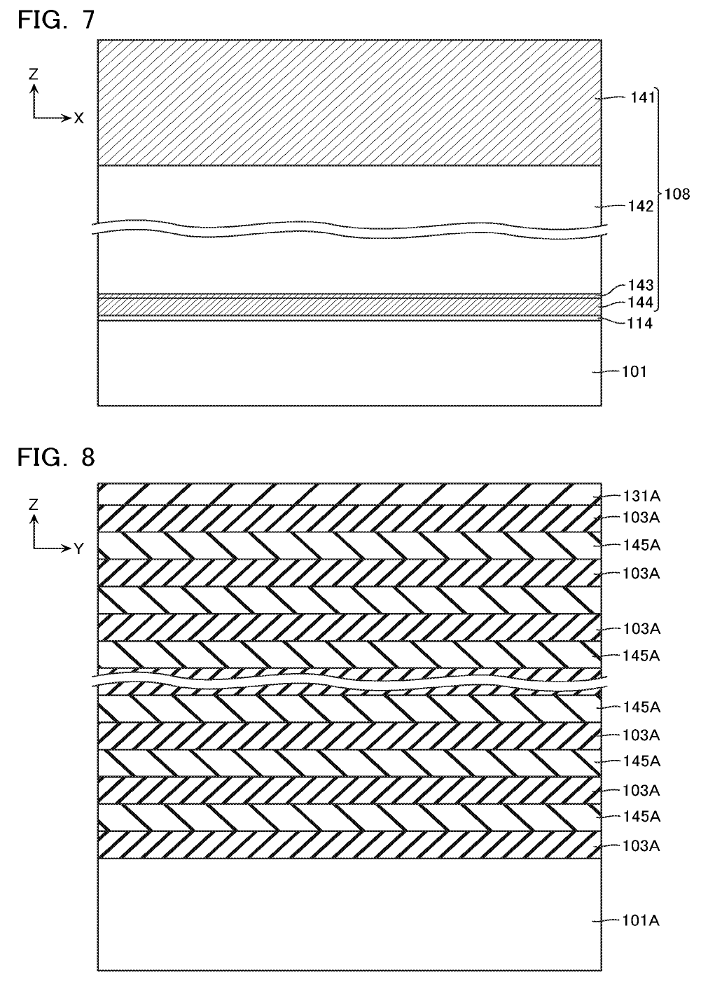

Next, the nonvolatile semiconductor memory device according to the present embodiment will be described in more detail with reference to FIGS. 5 to 7. FIG. 5 is a plan view showing a configuration of part of the memory cell array 1. FIG. 6 is a cross-sectional view showing a configuration of part of the memory cell array 1, and shows a cross-section of a portion indicated by the line AA in FIG. 3. FIG. 7 is a cross-sectional view showing a configuration of part of the memory cell array 1, and shows a cross-section of a portion indicated by the line BB in FIG. 3. Note that in FIGS. 5 to 7, part of the configuration is omitted.

As shown in FIG. 5, in the nonvolatile semiconductor memory device according to the present embodiment, a plurality of the conductive layers 102 having the X direction as their longitudinal direction are arranged in the Y direction. These conductive layers 102 are provided with a plurality of memory holes MH in the XY plane, and the memory columnar body 105 is provided inside the memory hole MH. Moreover, the memory columnar body 105 is connected to the bit line BL via a bit line contact BC. Moreover, provided between the conductive layers 102 adjacent in the Y direction, via an unillustrated inter-layer insulating layer, is the conductive layer 108 (source contact LI). Note that the conductive layer 108 is connected to the source line SL via a source line contact SC.

As shown in FIG. 6, the conductive layer 108 (source contact LI) according to the present embodiment has its lower end connected to the substrate 101, and has its upper end and its lower end configured from a metal silicide. The conductive layer 108 has a width in the Z direction of about 5 μm, for example, has a width in the Y direction of its upper end of about 80 to 90 nm, for example, and has a width in the Y direction of its lower end of about 60 to 70 nm, for example. Moreover, an insulating layer 134 is provided between the conductive layer 108 and the plurality of conductive layers 102.

As shown in FIG. 6, the conductive layer 108 comprises a silicide layer 144, a conductive layer 143, a silicon layer 142, and a silicide layer 141 that are stacked on the substrate 101. As shown in FIG. 7, the silicide layer 141 extends in the X direction. As shown in FIGS. 6 and 7, the silicon layer 142 is positioned below the silicide layer 141 and has a plate-like shape extending in the X direction along a lower surface of the silicide layer 141. As shown in FIG. 6, the conductive layer 143 covers side surfaces of the silicide layer 141 and silicon layer 142 and a lower surface of the silicon layer 142. As shown in FIG. 7, the silicide layer 144 extends in the X direction, contacts at its lower surface an upper surface of the substrate 101, and contacts at its upper end the conductive layer 143.

The silicide layer 141 is configured from the likes of nickel silicide (NiSiₓ), for example. The silicon layer 142 is configured from the likes of polysilicon, for example. The conductive layer 143 is configured from the likes of titanium nitride (TiN), for example. The silicide layer 144 is configured from the likes of titanium silicide (TiSiₓ), for example.

Now, in the present embodiment, the silicide layer 141 desirably has a low electrical resistance in the X direction. In order to lower the electrical resistance of the silicide layer 141, a film thickness of the silicide layer 141 is desirably large. From such a perspective, a cross-sectional area in the YZ plane of the silicide layer 141 is desirably 0.043 μm² or more. Moreover, when the film thickness of the silicide layer 141 becomes smaller than a certain amount, the silicide layer 141 behaves as a thin film not a bulk, hence its electrical resistance value ends up increasing. Therefore, the film thickness of the silicide layer 141 is desirably at least 500 nm or more.

Moreover, as will be described in detail later, in the present embodiment, the silicide layer 141 is formed by siliciding an upper portion of the silicon layer 142. Therefore, the silicide layer 141 and the silicon layer 142 have an integrally formed plate-like shape. Note that the silicide layer 141 and the silicon layer 142 have a width in the X direction and a width in the Z direction that are sufficiently longitudinal than a width in the Y direction.

Moreover, in the present embodiment, the silicide layer 141 is formed from nickel silicide. Now, nickel silicide has a comparatively low resistance among silicides. Moreover, nickel diffuses comparatively easily within silicon by heat treatment, hence the silicide layer 141 can be comparatively easily manufactured. Moreover, the silicide layer 141 may include both of nickel and cobalt (Co), for example. In this case, of metal atoms in the silicide layer 141, a percentage of nickel may be 85 to 95 at %, and a percentage of cobalt may be 5 to 15 at %, for example.

Moreover, the silicide layer 141 may also be formed from cobalt silicide (CoSiₓ), not nickel silicide. Furthermore, the silicide layer 141 may be formed from, for example, a silicide of comparatively low resistance, such as tungsten silicide (WSiₓ) or titanium silicide (TiSiₓ).

Moreover, in the present embodiment, the conductive layer 143 is formed from titanium nitride (TiN). However, the conductive layer may also be formed from the likes of tantalum nitride (TaN) or tungsten nitride (WN). Furthermore, the conductive layer 143 may have a stacked structure, not a single layer film.

Now, as shown in FIG. 6, the silicide layer 141 is electrically connected to the substrate 101 via the conductive layer 143 and the silicide layer 144. Moreover, in the present embodiment, the silicon layer 142 is configured from polysilicon, and the conductive layer 143 is configured from titanium nitride. Now, resistivity of titanium nitride is lower than that of polysilicon, regardless of whether the polysilicon is doped or not. For example, in the case of the polysilicon being doped, resistivity of the polysilicon, although depending also on a doping amount, is about 10 to 20 Ω·cm. In contrast, resistivity of titanium nitride, although depending also on a film thickness, is about 20 to 200 μΩ·cm. Therefore, a current flowing between the silicide layer 141 and the silicide layer 144 flows mainly via the conductive layer 143.

Now, in the present embodiment, current flows in the X direction within the conductive layer 108 (source contact LI). Therefore, a wiring line resistance R1 in the X direction in the conductive layer 108 is desirably low. Moreover, the conductive layer 108 is connected to the substrate 101. Therefore, a contact resistance Rc at a contact interface of the conductive layer 108 and the substrate 101 is also desirably low. Now, in order to reduce the wiring line resistance R1 and the contact resistance Rc, it is also conceivable to configure the entire conductive layer 108 from a metal material such as tungsten.

However, as a result of study by the inventors, it was found that if the entire conductive layer 108 is configured from tungsten, then warping ends up occurring in the substrate due to the influence of resultant stress. That is, a thermal expansion coefficient differs between a material such as silicon used in the substrate and a metal such as tungsten, hence a tensile stress on the substrate ends up occurring after deposition of tungsten. In particular, it is easy for tensile stress in the ZX plane to increase when the conductive layer 108 is formed in a plate shape extending in the ZX plane. Furthermore, the conductive layer 108 is connected at its lower surface to the substrate, and has a comparatively broad contact area with the substrate. It is therefore conceivable that tensile stress of the above-mentioned kind ends up occurring in a broad area, whereby the above-mentioned kind of substrate warping ends up occurring.

Now, as shown in FIG. 6, the conductive layer 108 according to the present embodiment has its upper end and its lower end configured from a metal silicide. The metal silicide has an electrical resistivity which is lower compared to that of polysilicon, and so on. Moreover, an ohmic junction is formed at a contact surface of silicon and the metal silicide. Furthermore, the metal silicide has a smaller difference between its thermal expansion coefficient and that of the substrate, compared to a metal material such as tungsten. Therefore, adopting the source contact LI whose upper end and lower end are configured from a metal silicide makes it possible to reduce tensile stress occurring in the substrate 101 while reducing the wiring line resistance R1 and the contact resistance Rc.

Moreover, in the present embodiment, nickel silicide is adopted as a material of the silicide layer 141, and in this case, the silicide layer 141 receives a compressive stress from the substrate 101. Furthermore, in the present embodiment, polysilicon is adopted as a material of the silicon layer 142, and in this case, the polysilicon layer 142 receives a tensile stress from the substrate 101. Therefore, adopting a stacked structure of the silicon layer 142 and the silicide layer 141 makes it possible for internal stresses between the silicon layer 142 and the silicide layer 141 to be canceled out, and tensile stress occurring in the substrate 101 to be further reduced.

[Method of Manufacturing]

Next, a method of manufacturing a nonvolatile semiconductor memory device according to the first embodiment will be described with reference to FIGS. 8 to 21. FIGS. 8 to 21 are cross-sectional views for explaining the method of manufacturing according to the first embodiment.

As shown in FIG. 8, in the method of manufacturing according to the present embodiment, a plurality of sacrifice layers 145A and inter-layer insulating layers 103A forming inter-layer insulating layers 103 are stacked alternately on a substrate 101A. Furthermore, an insulating layer 131A forming an insulating layer 131 is stacked in an even higher layer than the uppermost layer inter-layer insulating layer 103A. Note that the inter-layer insulating layer 103A is configured from, for example, silicon oxide (SiO₂). Moreover, the sacrifice layer 145A and the insulating layer 131A are configured from, for example, silicon nitride (SiN).

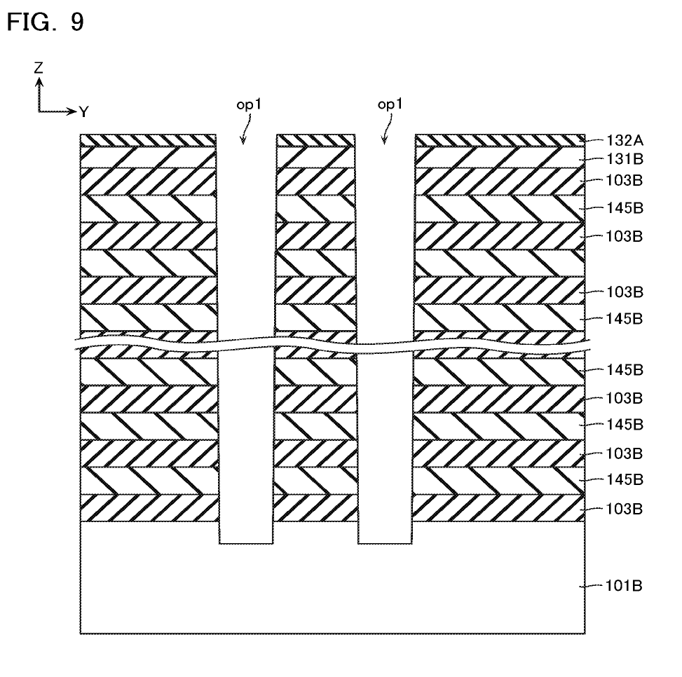

Next, as shown in FIG. 9, an insulating layer 132A forming an insulating layer 132 is stacked on the insulating layer 131A. The insulating layer 132A has an opening at a position where the memory columnar body 105 is formed. Next, an opening op1 penetrating an upper portion of the substrate 101A, the inter-layer insulating layer 103A, the sacrifice layer 145A, and the insulating layer 131A is formed using the insulating layer 132A as a mask, and a substrate 101B, an inter-layer insulating layer 103B, a sacrifice layer 145B, and an insulating layer 131B that are provided with the opening op1, are formed.

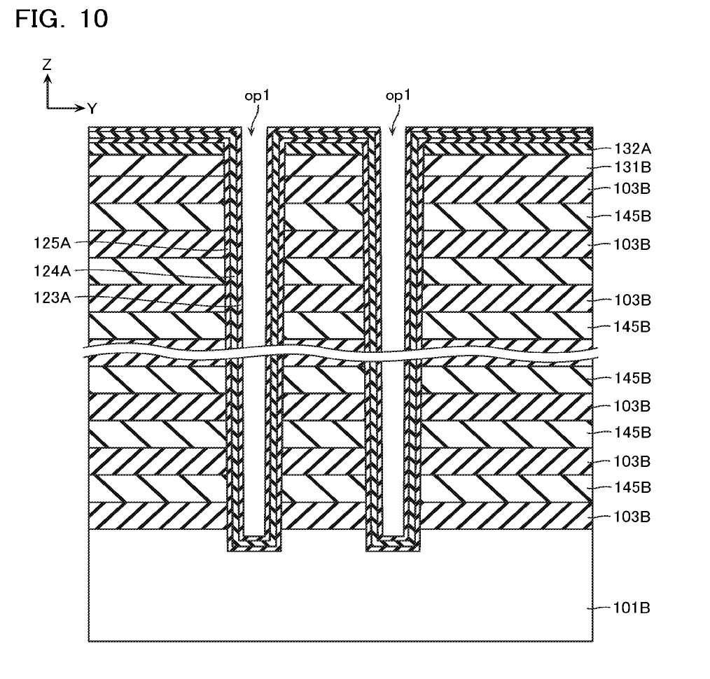

Next, as shown in FIG. 10, a block insulating layer formation layer 125A which will be the block insulating layer 125, a charge accumulation layer formation layer 124A which will be the charge accumulation layer 124, and a tunnel insulating layer formation layer 123A which will be the tunnel insulating layer 123 are formed on an upper surface of the insulating layer 132A and an inner wall of the opening op1.

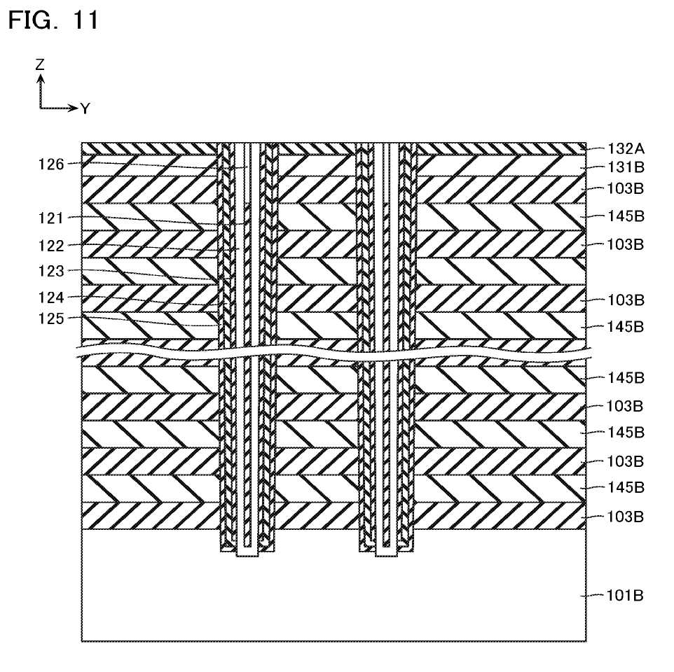

Next, as shown in FIG. 11, portions positioned at a bottom surface of the opening op1, of the block insulating layer formation layer 125A, the charge accumulation layer formation layer 124A, and the tunnel insulating layer formation layer 123A are removed, and the block insulating layer 125, the charge accumulation layer 124, and the tunnel insulating layer 123 are formed. Next, the semiconductor layer 122 is formed on a sidewall of the tunnel insulating layer 123, and furthermore, the core insulating layer 121 and a conductive layer 126 are implanted in a cavity covered by an inner wall of the semiconductor layer 122.

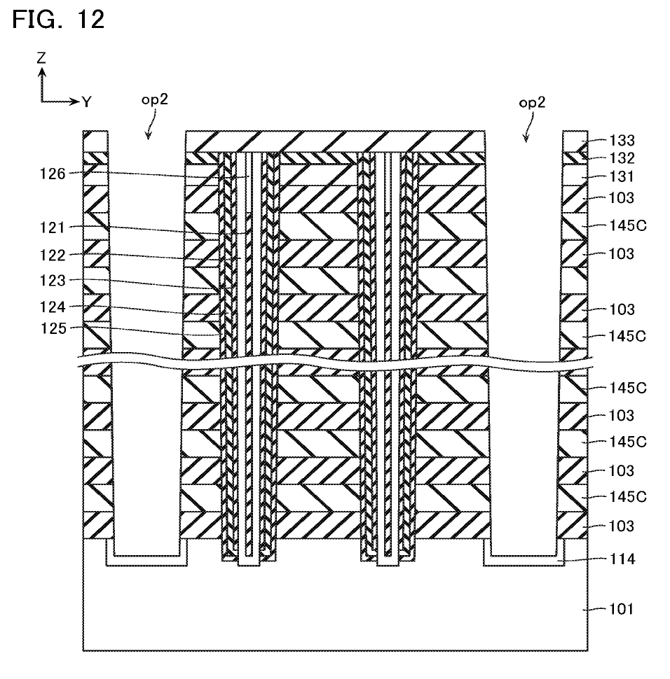

Next, as shown in FIG. 12, an insulating layer 133 is formed on an upper surface of the insulating layer 132A. The insulating layer 133 has an opening extending in the X direction, at a position where the conductive layer 108 (source contact LI) is formed. Furthermore, an opening op2 penetrating an upper portion of the substrate 101B, the inter-layer insulating layer 103B, the sacrifice layer 145B, the insulating layer 131B, and the insulating layer 132A is formed using the insulating layer 133 as a mask, and the substrate 101, the inter-layer insulating layer 103, a sacrifice layer 145C, the insulating layer 131, and the insulating layer 132 that are provided with the opening op2, are formed. Formation of the opening op2 is performed by a means such as dry etching, for example. The inter-layer insulating layer 103, the sacrifice layer 145C, the insulating layer 131, and the insulating layer 132 are divided in the Y direction via the opening op2. Next, an impurity is implanted in the substrate 101 via the opening op2, and a diffusion layer 114 is formed.

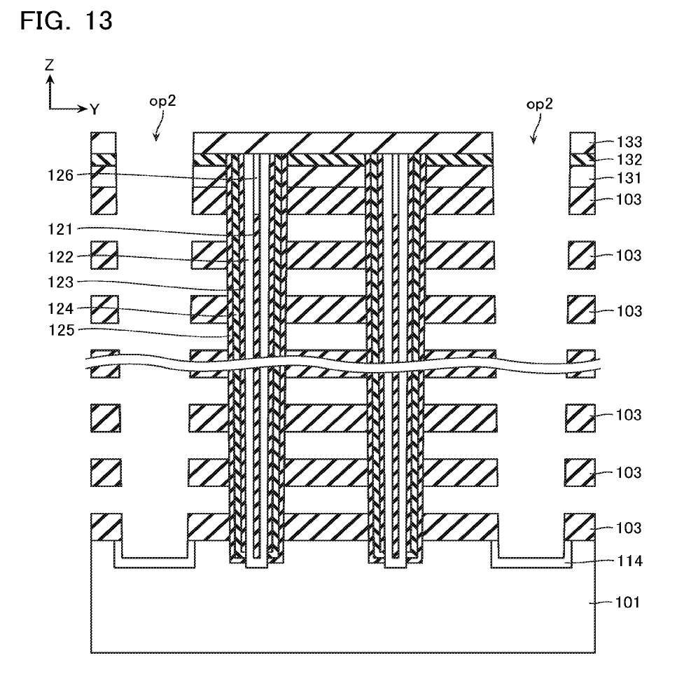

Next, as shown in FIG. 13, the sacrifice layer 145C is removed via the opening op2. Removal of the sacrifice layer 145C is performed by, for example, wet etching employing a phosphoric acid solution.

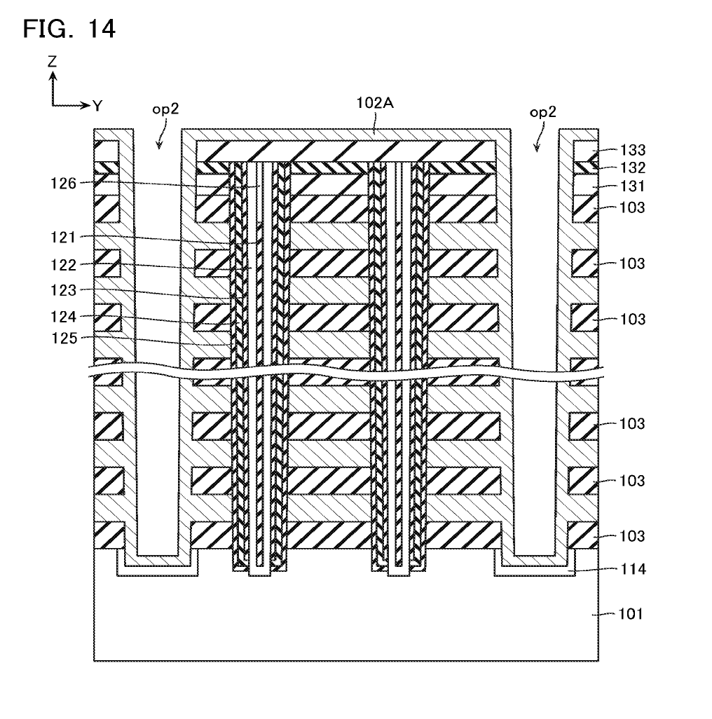

Next, as shown in FIG. 14, a conductive layer formation layer 102A forming the conductive layer 102 is formed between the inter-layer insulating layers 103 adjacent in the Z direction. The conductive layer formation layer 102A is formed between the stacked inter-layer insulating layers 103, via the opening op2.

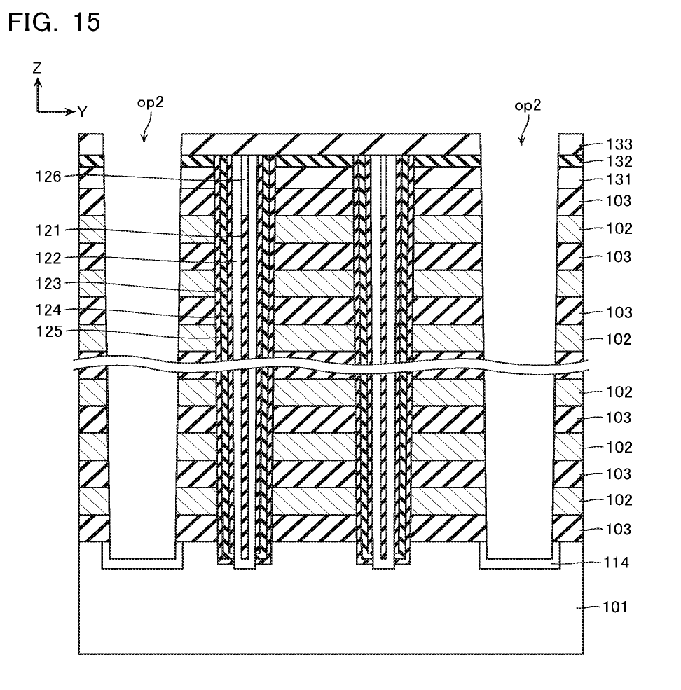

Next, as shown in FIG. 15, a portion covering an upper surface of the insulating layer 133 and a portion covering a sidewall of the inter-layer insulating layer 103, of the conductive layer formation layer 102A are removed, and the plurality of conductive layers 102 divided in the Z direction are formed.

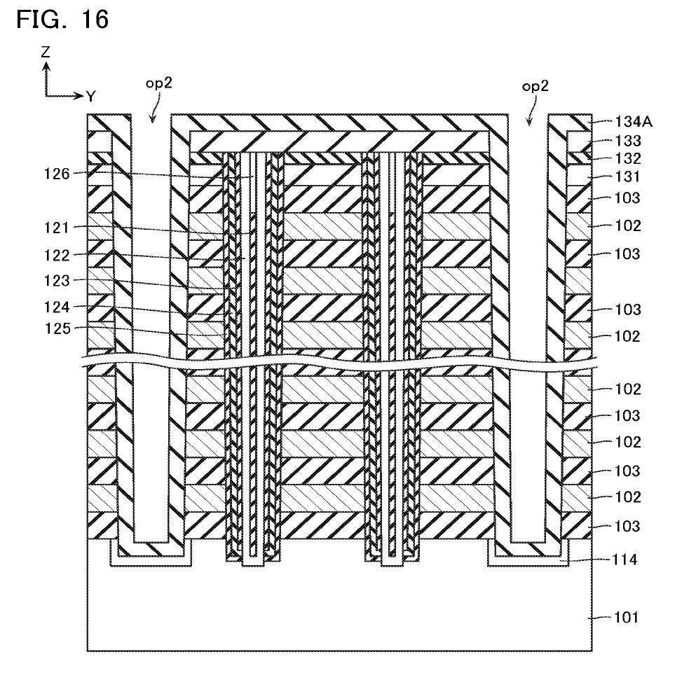

Next, as shown in FIG. 16, an insulating layer 134A is formed on the upper surface of the insulating layer 133, a side surface of the opening op2, and a bottom surface of the opening op2.

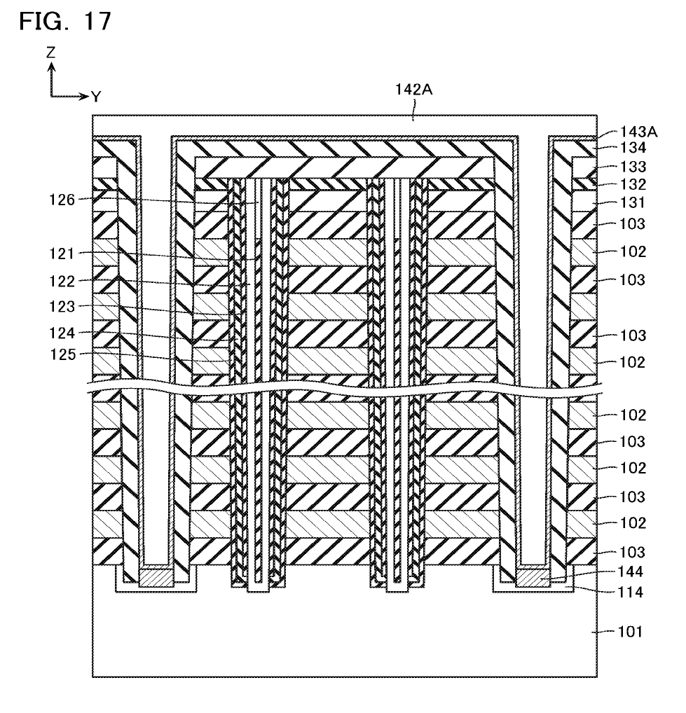

Next, as shown in FIG. 17, a portion positioned at the bottom surface of the opening op2, of the insulating layer 134A is removed, an insulating layer 134 is formed, and an upper surface portion of the substrate 101 positioned at the bottom surface of the opening op2 is exposed. Next, the silicide layer 144 is formed on the exposed portion of the substrate 101 upper surface. The silicide layer 144 is formed by, for example, depositing a metal such as titanium (Ti) in the opening op2 and performing heat treatment, and so on. As a result, the upper surface of the substrate 101 exposed in the opening op2 is silicided and the silicide layer 144 is formed. Next, a conductive layer 143A is formed on an upper surface of the insulating layer 134 and the side surface and bottom surface of the opening op2. The conductive layer 143A is formed by, for example, depositing a material such as titanium nitride. Next, in the same manufacturing method, a semiconductor layer 142A is implanted inside the opening op2. At this time, the semiconductor layer 142A is formed also on an upper surface of the conductive layer 143A.

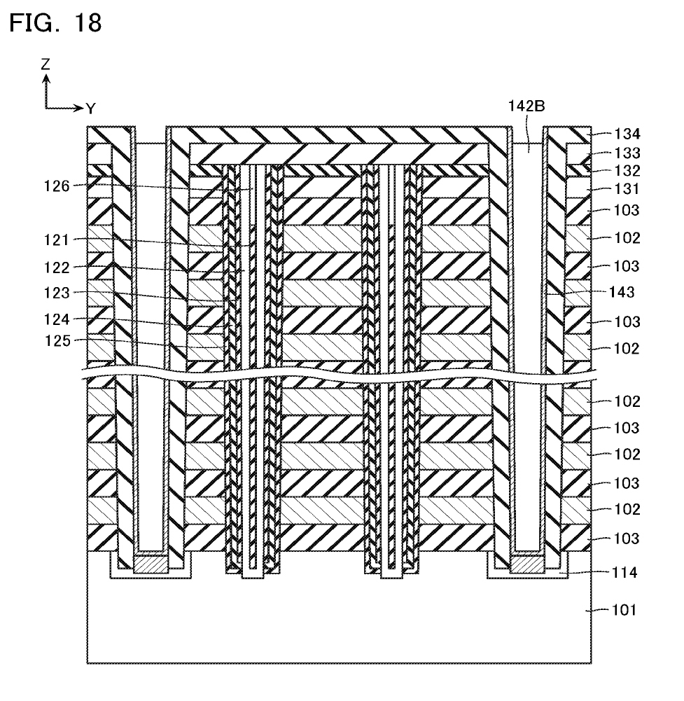

Next, as shown in FIG. 18, upper portions of the conductive layer 143A and the semiconductor layer 142A are removed, and the conductive layer 143 and a semiconductor layer 142B are formed. At this time, as shown in FIG. 18, a height of an upper surface of the semiconductor layer 142B may be set lower than a height of an upper surface of the insulating layer 134. A means such as etching, for example, is performed when removing the upper portions of the conductive layer 143A and the semiconductor layer 142A.

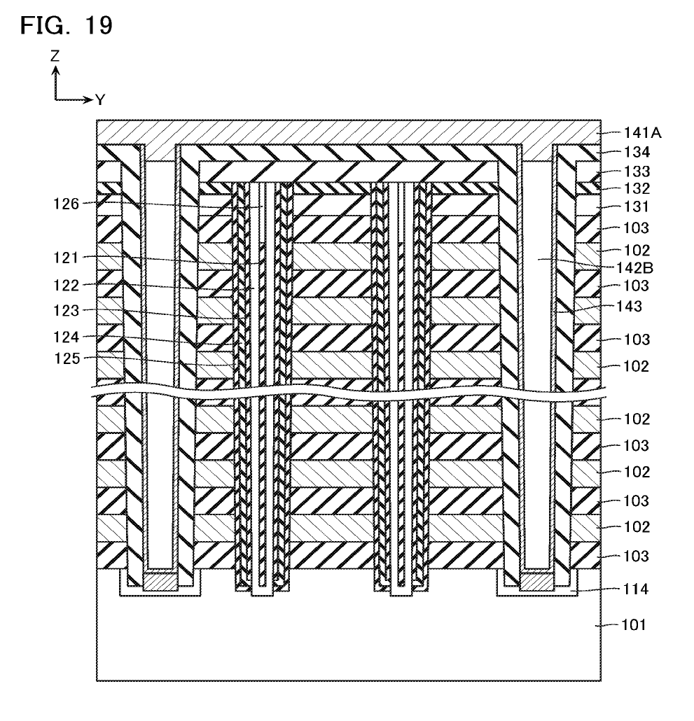

Next, as shown in FIG. 19, a metal layer 141A that provides metal atoms to the silicide layer 141 is formed on the upper surface of the semiconductor layer 142B and the upper surface of the insulating layer 134. The metal layer 141A according to the present embodiment is formed from, for example, nickel (Ni) or nickel to which cobalt (Co) has been added. However, the metal layer 141A may be formed from another metal, such as cobalt (Co), tungsten (W), or titanium (Ti). Formation of the metal layer 141A is performed by, for example, a method such as a PVD (Physical Vapor Deposition) method of the likes of sputtering. However, formation of the metal layer 141A may also be performed by a method such as a CVD (Chemical Vapor Deposition) method.

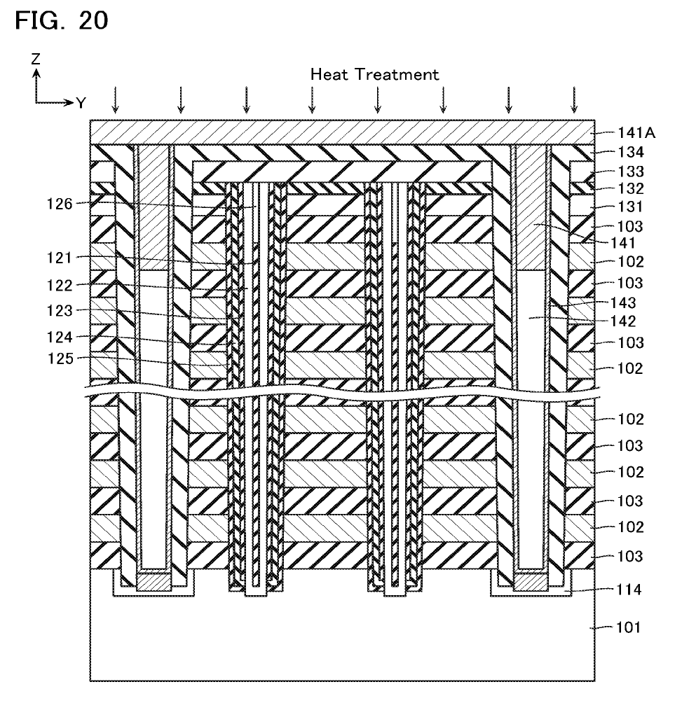

Next, as shown in FIG. 20, heat treatment is performed. As a result, metal atoms in the metal layer 141A diffuse in the semiconductor layer 142B, and the silicide layer 141 and semiconductor layer 142 are formed. The heat treatment is performed by, for example, a method such as an RTA (Rapid Thermal Annealing) method. Note that as shown in FIG. 20, silicon in the semiconductor layer 142B also sometimes diffuses in the metal layer 141A, and a height of an upper surface of the silicide layer 141 sometimes becomes higher than the height of the upper surface of the semiconductor layer 142B before heat treatment.

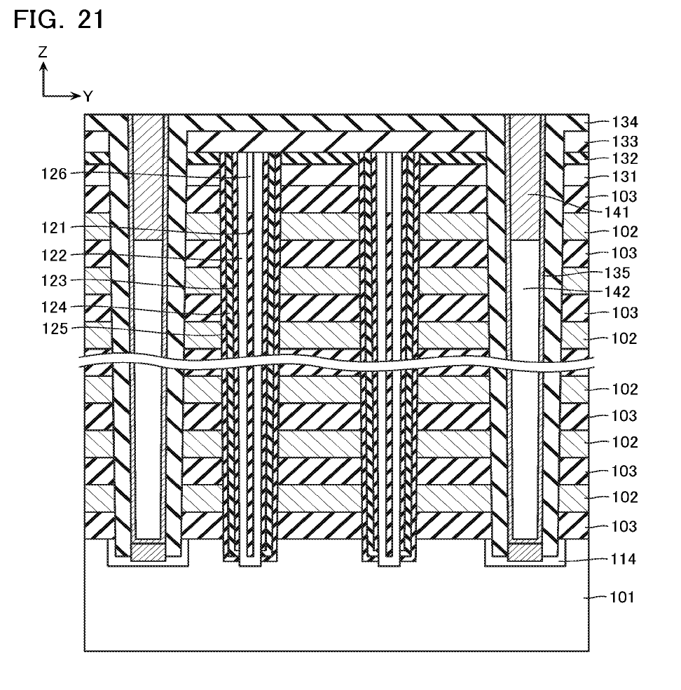

Next, as shown in FIG. 21, the metal layer 141A is removed. Removal of the metal layer 141A is performed by, for example, wet etching, a CMP (Chemical Mechanical Polishing) method, or dry etching of the likes of an RIE (Reactive Ion Etching) method, and so on.

Next, as shown in FIG. 6, the likes of the bit line contact BC connecting the semiconductor layer 122 and the conductive layer 106 (bit line BL) are formed. As a result, the nonvolatile semiconductor memory device described with reference to FIG. 6, and so on, is manufactured.

Now, as described with reference to FIGS. 17 and 20, in the method of manufacturing according to the present embodiment, a metal silicide is formed at the upper end and the lower end of the conductive layer 108. Therefore, as mentioned above, it is possible to reduce tensile stress occurring in the substrate 101 while reducing the wiring line resistance R1 and the contact resistance Rc.

Moreover, as described with reference to FIG. 19, in the method of manufacturing according to the present embodiment, the metal layer 141A is formed from nickel or nickel to which cobalt has been added. Now, as mentioned above, nickel diffuses comparatively easily in silicon by heat treatment. Therefore, a width in the Z direction of the silicide layer 141 can be comparatively easily increased to reduce the wiring line resistance R1.

Moreover, as described with reference to FIG. 20, in the method of manufacturing according to the present embodiment, metal in the metal layer 141A is diffused in the semiconductor layer 142 by heat treatment. Now, sometimes, when a temperature during the heat treatment gets too high, metal atoms coagulate in part of the semiconductor layer 142, whereby a discontinuation ends up occurring in the silicide layer 141. Now, using as the metal layer 141A nickel to which cobalt has been added makes it possible for the temperature at which such a phenomenon occurs (heat resistance temperature) to be set comparatively high. Moreover, as a result of study by the inventors, it was found to be preferable from a viewpoint of heat resistance temperature that, of metal atoms in the silicide layer 141, a percentage of nickel is 85 to 95 at %, and a percentage of cobalt is 5 to 15 at %. Note that in such a case, it is also possible for nickel to which 5 to 15 at % of cobalt has been added, to be set as a target of sputtering, and so on. Moreover, the heat treatment may be performed in a range of 500° C. to 600° C.

Moreover, as described with reference to FIG. 18, the height of the upper surface of the semiconductor layer 142B may be set lower than the height of the upper surface of the insulating layer 134. Now, the height of the upper surface of the semiconductor layer 142B can be set based on the likes of an amount or range of silicon that diffuses in the metal layer 141A. That is, as mentioned above, heat treatment causes nickel to diffuse comparatively easily in silicon, and causes silicon to diffuse with comparative difficulty in nickel. On the other hand, heat treatment causes cobalt or tungsten, titanium, and so on, to diffuse with comparative difficulty in silicon, and causes silicon to diffuse comparatively easily in these metals. Therefore, it is also conceivable that when the metal layer 141A is of cobalt or tungsten, titanium, and so on, the height of the upper layer of the semiconductor layer 142B is set comparatively low.

Moreover, as described with reference to FIG. 19, in the method of manufacturing according to the present embodiment, the metal layer 141A is formed using a PVD method such as sputtering. Now, in the method of manufacturing according to the present embodiment, the metal layer 141A need only contact the upper surface of the semiconductor layer 142B, and a high degree of implanting capability is not required. Therefore, by forming the metal layer 141A using a PVD method such as sputtering, manufacturing costs can be further cut compared to when using the likes of a CVD method.

Moreover, as described with reference to FIG. 21, in the present embodiment, the metal layer 141A is removed by the likes of wet etching, CMP, or dry etching. Now, in the case that removal of the metal layer 141A is performed using wet etching, manufacturing costs can be further cut compared to when CMP or dry etching is used. On the other hand, in the present embodiment, in the step described with reference to FIG. 20, the upper surface of the insulating layer 134 sometimes gets silicided. Now, it is conceivable that when the bit line contact BC shown in FIG. 6 is formed in a state where the upper surface of the insulating layer 134 is silicided, the source line SL (refer to FIG. 2) and the bit line BL (refer to FIG. 2) get short-circuited. In such a case, it is also possible that by employing the likes of CMP or dry etching, silicide formed on the upper surface of the insulating layer 134 is removed along with the metal layer 141 and short-circuiting is prevented.

### Other Embodiments

As described with reference to FIG. 6, in the first embodiment, the conductive layer 108 comprised the silicide layer 144, the conductive layer 143, the silicon layer 142, and the silicide layer 141 stacked on the substrate 101. However, the conductive layer 108 need only include a metal silicide at its upper end and its lower end. Therefore, it is also possible for the conductive layer 108 to be configured as a single layer of metal silicide, for example.

Note that when the conductive layer 108 is configured as a single layer of metal silicide, it is conceivable in the step described with reference to FIG. 17 to, for example, form the semiconductor layer 142A along the sidewall of the opening op2 with a thickness of a degree that the opening op2 is not filled in, implant the metal layer 141A (refer to FIG. 19) therein, and perform heat treatment. It is also conceivable that in such a case, the metal layer 141A is formed by a method such as a CVD method, not a PVD method.

[Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a plurality of control gate electrodes stacked above a substrate;
a semiconductor layer having one end thereof connected to the substrate, the semiconductor layer having as its longitudinal direction a direction perpendicular to the substrate, and the semiconductor layer facing the plurality of control gate electrodes;
a charge accumulation layer positioned between the control gate electrode and the semiconductor layer; and
a contact having a lower end thereof connected to the substrate, the lower end and an upper end of the contact being configured from a metal silicide.

2. The semiconductor memory device according to claim 1, wherein
the contact has a width in a first direction which is larger than a width in a second direction intersecting the first direction, in a plane parallel to the substrate.

3. The semiconductor memory device according to claim 1, wherein
a width of at least 500 nm or more in a downward direction from the upper end, of the contact is configured from the metal silicide.

4. The semiconductor memory device according to claim 1, wherein
the contact comprises:
a first metal silicide layer contacting at its lower surface an upper surface of the substrate;
a silicon layer positioned above the first metal silicide layer; and
a second metal silicide layer positioned above the silicon layer.

5. The semiconductor memory device according to claim 4, wherein
the contact further comprises a first conductive layer, the first conductive layer covering side surfaces of the silicon layer and second metal silicide layer and a lower surface of the silicon layer.

6. The semiconductor memory device according to claim 5, wherein
the second metal silicide layer has a width in a first direction which is larger than a width in a second direction intersecting the first direction, in a plane parallel to the substrate, and
the first conductive layer covers both side surfaces in the second direction, of the silicon layer and the second metal silicide layer.

7. The semiconductor memory device according to claim 4, wherein
the second metal silicide layer includes at least one of nickel and cobalt.

8. The semiconductor memory device according to claim 4, wherein
the second metal silicide layer includes both of nickel and cobalt.

9. The semiconductor memory device according to claim 8, wherein
of metal atoms in the second metal silicide layer,
a percentage of nickel is 85 to 95 at %, and
a percentage of cobalt is 5 to 15 at %.

10. A method of manufacturing a semiconductor memory device, comprising:
alternately stacking a plurality of inter-layer insulating layers and first layers above a substrate to form a stacked body;
forming a through hole, the through hole penetrating the stacked body;
forming a semiconductor layer inside the through hole, the semiconductor layer having as its longitudinal direction a direction perpendicular to the substrate, and the semiconductor layer facing the plurality of inter-layer insulating layers and first layers;
forming a trench, the trench dividing the stacked body; and
forming a contact on a portion exposed via the trench, of an upper surface of the substrate, a lower end and an upper end of the contact being configured from a metal silicide.

11. The method of manufacturing a semiconductor memory device according to claim 10, comprising:
after forming the trench and before forming the contact,
removing the first layer; and
forming a first conductive layer between the stacked inter-layer insulating layers, the first conductive layer facing the semiconductor layer.

12. The method of manufacturing a semiconductor memory device according to claim 10, comprising
forming the metal silicide in a width of at least 500 nm or more in a downward direction from the upper end, of the contact.

13. The method of manufacturing a semiconductor memory device according to claim 10, comprising:
forming a first metal silicide layer on the portion exposed via the trench, of the upper surface of the substrate;
forming a silicon layer above the first metal silicide layer; and
siliciding an upper portion of the silicon layer to form a second metal silicide layer.

14. The method of manufacturing a semiconductor memory device according to claim 13, comprising:
after forming the trench and before forming the first metal silicide layer, forming a first insulating layer, the first insulating layer covering side surfaces of the plurality of inter-layer insulating layers; and
after forming the first metal silicide layer and before forming the silicon layer, forming a second conductive layer, the second conductive layer covering a side surface of the first insulating layer and an upper surface of the first metal silicide layer.

15. The method of manufacturing a semiconductor memory device according to claim 13, comprising:
forming a metal layer in an upper portion of the silicon layer;
performing heat treatment; and
removing at least part of the metal layer.

16. The method of manufacturing a semiconductor memory device according to claim 15, comprising
removing part of the first insulating layer along with the metal layer.

17. The method of manufacturing a semiconductor memory device according to claim 14, comprising
after forming the silicon layer and before forming the second metal silicide layer, setting a height of an upper surface of the silicon layer lower than a height of an upper surface of the first insulating layer.

18. The method of manufacturing a semiconductor memory device according to claim 13, wherein
the second metal silicide layer includes at least one of nickel and cobalt.

19. The method of manufacturing a semiconductor memory device according to claim 13, wherein
the second metal silicide layer includes both of nickel and cobalt.

20. The method of manufacturing a semiconductor memory device according to claim 19, wherein
of metal atoms in the second metal silicide layer,
a percentage of nickel is 85 to 95 at %, and
a percentage of cobalt is 5 to 15 at %.
